(19) United States
(12) Patent Application Publication
(10) Pub. No.: US 2024/0162877 A1
(43) Pub. Date: May 16, 2024

(54) MULTILAYER ELECTRONIC COMPONENT

(71) Applicant: TDK CORPORATION, Tokyo (JP)

(72) Inventor: Toshiyuki TAKAMI, Tokyo (JP)

(73) Assignee: TDK CORPORATION, Tokyo (JP)

(21) Appl. No.: 18/501,635

(22) Filed: Nov. 3, 2023

(30) Foreign Application Priority Data
Nov. 10, 2022 (JP) 2022-180601

(51) Int. Cl. H03H 7/01; H01F 27/40; H01G 4/40

(52) U.S. Cl. CPC H03H 7/0115; H01F 27/40; H01G 4/40

(57) ABSTRACT

An electronic component includes a plurality of resonators and a stack. Each of the plurality of resonators includes a first through hole line, a second through hole line, and a conductor layer portion. The second through hole line is provided between the conductor layer portion and ground in a circuit configuration. The stack includes a first region and a second region. The first region and the second region are divided by a plurality of second through hole lines.

### CROSS REFERENCE TO RELATED APPLICATIONS

This application claims the benefit of Japanese Priority Patent Application No. 2022-180601 filed on Nov. 10, 2022, the entire contents of which are incorporated herein by reference.

### BACKGROUND OF THE INVENTION

### 1. Field of the Invention

The present invention relates to a multilayer electronic component including a plurality of resonators.

### 2. Description of the Related Art

Compact mobile communication apparatuses are generally configured to use a single common antenna for a plurality of applications that use different systems and have different service frequency bands, and to use a branching filter to separate a plurality of signals received and transmitted by the antenna from each other.

A branching filter for separating a first signal of a frequency within a first frequency band and a second signal of a frequency within a second frequency band higher than the first frequency band from each other typically includes a common port, a first signal port, a second signal port, a first filter provided in a first signal path leading from the common port to the first signal port, and a second filter provided in a second signal path leading from the common port to the second signal port.

As the first filter, a band-pass filter including a plurality of resonators configured to electromagnetically coupled with each other is used, for example. Such a band-pass filter will be referred to as a resonant band-pass filter below. JP 2014-27690 A1 discloses a resonant band-pass filter.

As the second filter, a high-pass filter or a band-pass filter constituted by connecting a high-pass filter and a low-pass filter in series can be used, for example.

The recent market demands for reductions in size and footprint of the compact mobile communication apparatuses and also requires miniaturization of branching filters for use in those communication apparatuses. As a branching filter suitable for miniaturization, known is a branching filter using a stack including a plurality of dielectric layers and a plurality of conductor layers stacked together. However, when the branching filter is reduced in size, a problem arises that isolation between the first filter and the second filter is degraded.

The foregoing problem is not limited to branching filters and applies to multilayer electronic components in general each including two regions for which isolation need be secured.

### SUMMARY OF THE INVENTION

An object of the present invention is to provide a multilayer electronic component that can ensure isolation between two regions.

A multilayer electronic component of the present invention includes: a plurality of resonators; and a stack for integrating the plurality of resonators, the stack including a plurality of dielectric layers stacked together. Each of the plurality of resonators includes a first through hole line, a second through hole line, and a conductor layer portion connecting the first through hole line and the second through hole line. Each of the first through hole line and the second through hole line is constituted by two or more through holes being connected in series. The second through hole line is provided between the conductor layer portion and ground in a circuit configuration. The stack includes a first region and a second region in each of which at least one element is arranged. The first region and the second region are divided by a plurality of second through hole lines.

In the multilayer electronic component of the present invention, the second through hole line is provided between the conductor layer portion and the ground in the circuit configuration. The first region and the second region are divided by the plurality of second through hole lines. Thus, according to the present invention, it is possible to ensure isolation between the first region and the second region.

Other and further objects, features and advantages of the present invention will appear more fully from the following description.

### BRIEF DESCRIPTION OF THE DRAWINGS

FIG. 1 is a circuit diagram showing a circuit configuration of a multilayer electronic component according to an embodiment of the present invention.

FIG. 2 is a perspective view showing an appearance of the multilayer electronic component according to the embodiment of the present invention.

FIG. 3A to FIG. 3C are explanatory diagrams showing respective patterned surfaces of first to third dielectric layers of a stack of the multilayer electronic component according to the embodiment of the present invention.

FIG. 4A to FIG. 4C are explanatory diagrams showing respective patterned surfaces of fourth to sixth dielectric layers of the stack of the multilayer electronic component according to the embodiment of the present invention.

FIG. 5A is an explanatory diagram showing a patterned surface of a seventh dielectric layer of the stack of the multilayer electronic component according to the embodiment of the present invention.

FIG. 5B is an explanatory diagram showing a patterned surface of an eighth dielectric layer of the stack of the multilayer electronic component according to the embodiment of the present invention.

FIG. 5C is an explanatory diagram showing a patterned surface of each of ninth to seventeenth dielectric layers of the stack of the multilayer electronic component according to the embodiment of the present invention.

FIG. 6A to FIG. 6C are explanatory diagrams showing respective patterned surfaces of eighteenth to twentieth dielectric layers of the stack of the multilayer electronic component according to the embodiment of the present invention.

FIG. 7A and FIG. 7B are explanatory diagrams showing respective patterned surfaces of twenty-first and twenty-second dielectric layers of the stack of the multilayer electronic component according to the embodiment of the present invention.

FIG. 8 is a perspective view showing an inside of the stack of the multilayer electronic component according to the embodiment of the present invention.

FIG. 9 is a plan view showing the inside of the stack of the multilayer electronic component according to the embodiment of the present invention.

FIG. 10 is a side view showing the inside of the stack of the multilayer electronic component according to the embodiment of the present invention.

### DETAILED DESCRIPTION OF THE PREFERRED EMBODIMENTS

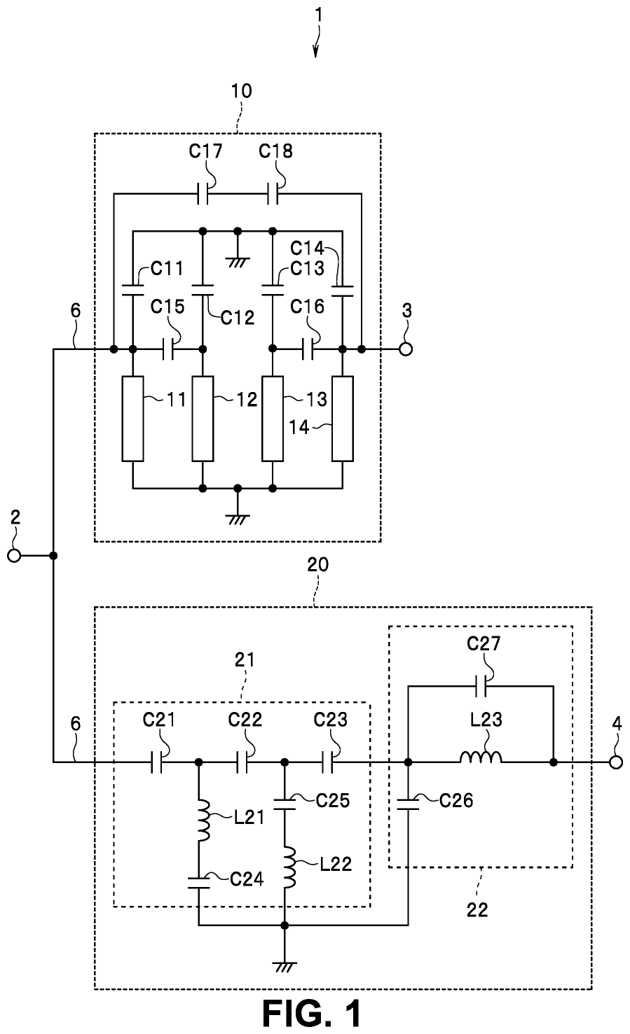

An embodiment of the present invention will now be described in detail with reference to the drawings. First, a configuration of a multilayer electronic component (hereinafter simply referred to as electronic component) 1 according to the embodiment of the present invention will be outlined with reference to FIG. 1. The electronic component 1 according to the present embodiment includes at least a plurality of resonators.

FIG. 1 shows a branching filter (diplexer) as an example of the electronic component 1 including the plurality of resonators. The branching filter, in other words, the electronic component 1, includes a first filter 10 that selectively passes a first signal of a frequency within a first passband, and a second filter 20 that selectively passes a second signal of a frequency within a second passband higher than the first passband. The first filter 10 corresponds to a “first circuit portion” of the present invention. The second filter 20 corresponds to a “second circuit portion” of the present invention.

The electronic component 1 further includes a first port 2, a second port 3, a third port 4, a signal path 5 connecting the first port 2 and the second port 3, and a signal path 6 connecting the first port 2 and the third port 4. The first filter 10 is provided between the first port 2 and the second port 3 in a circuit configuration. The second filter 20 is provided between the first port 2 and the third port 4 in the circuit configuration. In the present application, the expression of “in the (a) circuit configuration” is used to indicate not layout in a physical configuration but layout in the circuit diagram.

The signal path 5 is a path leading from the first port 2 to the second port 3 via the first filter 10. The signal path 6 is a path leading from the first port 2 to the third port 4 via the second filter 20. The first signal of a frequency within the first passband selectively passes through the signal path 5 on which the first filter 10 is provided. The second signal of a frequency within the second passband selectively passes through the signal path 6 on which the second filter 20 is provided. In such a manner, the electronic component 1 separates the first signal and the second signal.

In the present embodiment, the first filter 10 is a band-pass filter circuit including the plurality of resonators. The second filter 20 includes a high-pass filter circuit 21 and a low-pass filter circuit 22 provided between the high-pass filter circuit 21 and the third port 4. The high-pass filter circuit 21 and the low-pass filter circuit 22 constitute a band-pass filter.

Since the first and second filters 10 and 20 are components of the electronic component 1, this can be interpreted as the electronic component 1 including the band-pass filter circuit, the high-pass filter circuit 21, and the low-pass filter circuit 22.

Next, an example of configurations of the first and second filters 10 and 20 will be described with reference to FIG. 1. The first filter 10 will initially be described. The first filter 10 includes resonators 11, 12, 13, and 14 and capacitors C11, C12, C13, C14, C15, C16, C17, and C18.

The resonators 11 to 14 are arranged in this order from the first port 2 side in the circuit configuration. The resonators 11 to 14 are configured so that the resonators 11 and 12 are adjacent to each other in the circuit configuration to be electromagnetically coupled, the resonators 12 and 13 are adjacent to each other in the circuit configuration to be electromagnetically coupled, and the resonators 13 and 14 are adjacent to each other in the circuit configuration to be electromagnetically coupled. In the present embodiment, each of the resonators 11 to 14 is a quarter-wavelength resonator.

Each of the resonators 11 to 14 includes a first end and a second end. The first end of the resonator 11 is connected to the first port 2. The first end of the resonator 14 is connected to the second port 3. The second end of each of the resonators 11 to 14 is grounded.

The capacitor C11 is arranged between the first end of the resonator 11 and the ground in the circuit configuration. The capacitor C12 is arranged between the first end of the resonator 12 and the ground in the circuit configuration. The capacitor C13 is arranged between the first end of the resonator 13 and the ground in the circuit configuration. The capacitor C14 is arranged between the first end of the resonator 14 and the ground in the circuit configuration.

The resonator 11 and the resonator 12 are capacitive-coupled via the capacitor C15. The resonator 13 and the resonator 14 are capacitive-coupled via the capacitor C16.

The resonators 11 to 14 are connected in parallel with each other. Specifically, the first ends or the second ends of any two resonators of the resonators 11 to 14 are connected to each other directly or via a capacitor(s).

One end of the capacitor C17 is connected to the first end of the resonator 11. One end of the capacitor C18 is connected to the other end of the capacitor C17. The other end of the capacitor C18 is connected to the first end of the resonator 14.

Next, the high-pass filter circuit 21 of the second filter 20 will be described. The high-pass filter circuit 21 includes inductors L21 and L22 and capacitors C21, C22, C23, C24, and C25.

One end of the capacitor C21 is connected to the first port 2. One end of the capacitor C22 is connected to the other end of the capacitor C21. One end of the capacitor C23 is connected to the other end of the capacitor C22.

One end of the inductor L21 is connected to a connection point between the capacitor C21 and the capacitor C22. One end of the capacitor C24 is connected to the other end of the inductor L21. The other end of the capacitor C24 is grounded.

One end of the capacitor C25 is connected to a connection point between the capacitor C22 and the capacitor C23. One end of the inductor L22 is connected to the other end of the capacitor C25. The other end of the inductor L22 is grounded.

Next, the low-pass filter circuit 22 of the second filter 20 will be described. The low-pass filter circuit 22 includes an inductor L23 and capacitors C26 and C27. One end of the inductor L23 is connected to the other end of the capacitor C23 of the high-pass filter circuit 21. The other end of the inductor L23 is connected to the third port 4.

One end of the capacitor C26 is connected to the one end of the inductor L23. The other end of the capacitor C26 is grounded. The capacitor C27 is connected in parallel with the inductor L23.

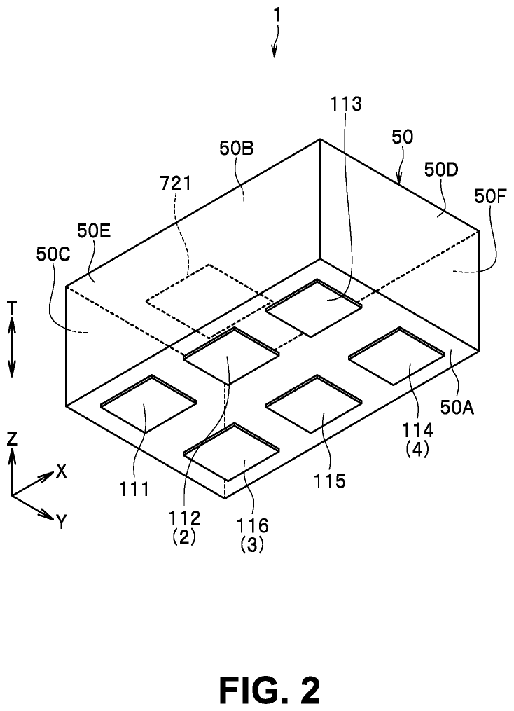

Next, other configurations of the electronic component 1 will be described with reference to FIG. 2. FIG. 2 is a perspective view showing an appearance of a stack of the electronic component 1.

The electronic component 1 further includes a stack 50 including a plurality of dielectric layers and a plurality of conductors (a plurality of conductor layers and a plurality of through holes) stacked together. The stack 50 is for integrating the first to third ports 2 to 4, the first filter 10 being a band-pass filter including the resonators 11 to 14, and the second filter 20 including the high-pass filter circuit 21 and the low-pass filter circuit 22.

The stack 50 has a bottom surface 50A and a top surface 50B located at both ends in a stacking direction T of the plurality of dielectric layers, and four side surfaces 50C to 50F connecting the bottom surface 50A and the top surface 50B. The side surfaces 50C and 50D are opposite to each other. The side surfaces 50E and 50F are opposite to each other. The side surfaces 50C to 50F are perpendicular to the top surface 50B and the bottom surface 50A.

Here, X, Y, and Z directions are defined as shown in FIG. 2. The X, Y, and Z directions are orthogonal to one another. In the present embodiment, a direction parallel to the stacking direction T will be referred to as the Z direction. The opposite directions to the X, Y, and Z directions are defined as −X, −Y, and −Z directions, respectively. The expression of “when seen from the stacking direction T” means that an object is seen from a position away in the Z direction or the −Z direction.

As shown in FIG. 2, the bottom surface 50A is located at the end of the stack 50 in the —Z direction. The top surface 50B is located at the end of the stack 50 in the Z direction. The side surface 50C is located at the end of the stack 50 in the −X direction. The side surface 50D is located at the end of the stack 50 in the X direction. The side surface 50E is located at the end of the stack 50 in the —Y direction. The side surface 50F is located at the end of the stack 50 in the Y direction.

The planar shape of the stack 50 when seen from the stacking direction T, in other words, the shape of the bottom surface 50A or the top surface 50B, is a shape being long in one direction. In the present embodiment, in particular, the planar shape of the stack 50 when seen from the stacking direction T is a rectangular shape being long in a direction parallel to the X direction.

The electronic component 1 further includes terminals 111, 112, 113, 114, 115, and 116 provided on the bottom surface 50A of the stack 50. The terminals 111, 112, and 113 are arranged in this order in the X direction at positions closer to the side surface 50E than the side surface 50F. The terminals 114, 115, and 116 are arranged in this order in the −X direction at positions closer to the side surface 50F than the side surface 50E.

The terminal 112 is a signal terminal corresponding to the first port 2. The terminal 114 is a signal terminal corresponding to the third port 4. The terminal 116 is a signal terminal corresponding to the second port 3. The first to third ports 2 to 4 are thus provided on the bottom surface 50A of the stack 50. Each of the terminals 111, 113, and 115 is grounded.

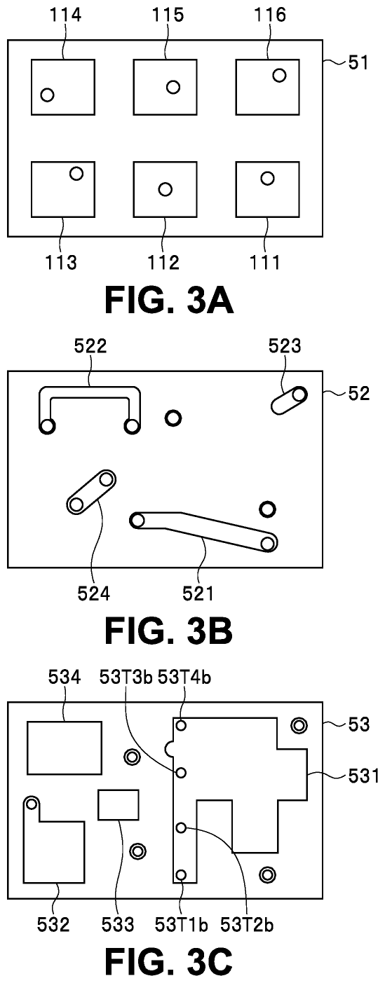

Next, an example of the plurality of dielectric layers and the plurality of conductors constituting the stack 50 will be described with reference to FIG. 3A to FIG. 7B. In this example, the stack 50 includes twenty-two dielectric layers stacked together. In the following, the twenty-two dielectric layers will be referred to as the first to twenty-second dielectric layers in the order from bottom to top. The first to twenty-second dielectric layers are denoted by reference numerals 51 to 72, respectively.

In FIG. 3A to FIG. 6C, each circle represents a through hole. The dielectric layers 51 to 70 each have a plurality of through holes. The plurality of through holes are each formed by filling a hole intended for a through hole with a conductive paste. Each of the plurality of through holes is connected to a conductor layer or another through hole. In FIG. 3A to FIG. 6C, a plurality of specific through holes of the plurality of through holes are denoted by reference numerals.

FIG. 3A shows a patterned surface of the first dielectric layer 51. The terminals 111 to 116 are formed on the patterned surface of the dielectric layer 51. FIG. 3B shows a patterned surface of the second dielectric layer 52. Conductor layers 521, 522, 523, and 524 are formed on the patterned surface of the dielectric layer 52.

FIG. 3C shows a patterned surface of the third dielectric layer 53. Conductor layers 531, 532, 533 and 534 are formed on the patterned surface of the dielectric layer 53. Four through holes denoted by respective reference numerals 53T1b, 53T2b, 53T3b, and 53T4b in FIG. 3C are connected to the conductor layer 531. Note that the through hole denoted by the reference numeral 53T1b is referred to simply as a through hole 53T1b in the following description. A through hole denoted by a reference numeral other than the through hole 53T1b is referred to similarly to the through hole 53T1b.

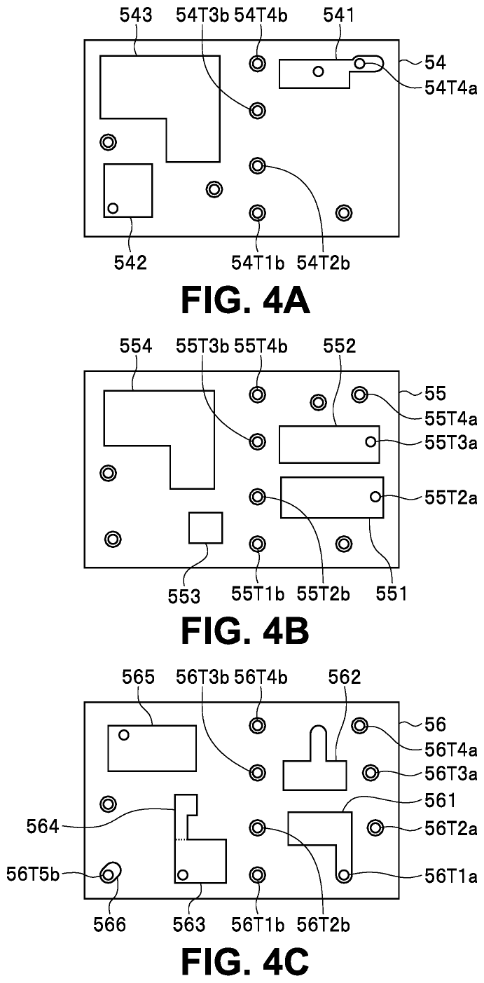

FIG. 4A shows a patterned surface of the fourth dielectric layer 54. Conductor layers 541, 542, and 543 are formed on the patterned surface of the dielectric layer 54.

Through holes 54T1b, 54T2b, 54T3b, and 54T4b shown in FIG. 4A are connected to the through holes 53T1b, 53T2b, 53T3b, and 53T4b formed in the dielectric layer 53, respectively. The through hole 54T4a shown in FIG. 4A is connected to the conductor layer 541.

FIG. 4B shows a patterned surface of the fifth dielectric layer 55. Conductor layers 551, 552, 553, and 554 are formed on the patterned surface of the dielectric layer 55.

Through holes 55T1b, 55T2b, 55T3b, 55T4a, and 55T4b shown in FIG. 4B are connected to the through holes 54T1b, 54T2b, 54T3b, 54T4a, and 54T4b formed in the dielectric layer 54, respectively. Through holes 55T2a and 55T3a shown in FIG. 4B are connected to the conductor layers 551 and 552, respectively.

FIG. 4C shows a patterned surface of the sixth dielectric layer 56. Conductor layers 561, 562, 563, 564, 565, and 566 are formed on the patterned surface of the dielectric layer 56. The conductor layer 564 is connected to the conductor layer 563. In FIG. 4C, the boundary between the conductor layer 563 and the conductor layer 564 is indicated by a dotted line.

Through holes 56T1a and 56T5b shown in FIG. 4C are connected to the conductor layers 561 and 566, respectively. Through holes 56T1b, 56T2a, 56T2b, 56T3a, 56T3b, 56T4a, and 56T4b shown in FIG. 4C are connected to the through holes 55T1b, 55T2a, 55T2b, 55T3a, 55T3b, 55T4a, and 55T4b formed in the dielectric layer 55, respectively.

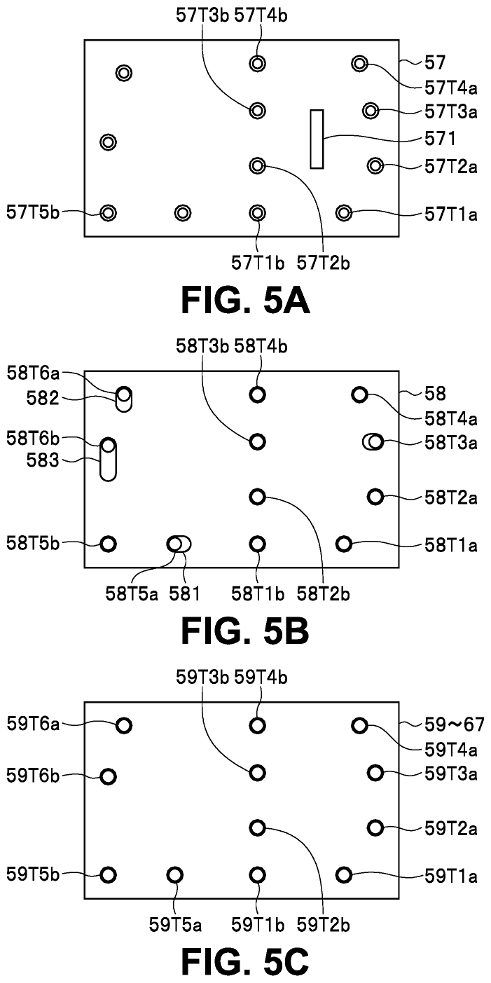

FIG. 5A shows a patterned surface of the seventh dielectric layer 57. A conductor layer 571 is formed on the patterned surface of the dielectric layer 57. Through holes 57T1a, 57T1b, 57T2a, 57T2b, 57T3a, 57T3b, 57T4a, 57T4b, and 57T5b shown in FIG. 5A are connected to the through holes 56T1a, 56T1b, 56T2a, 56T2b, 56T3a, 56T3b, 56T4a, 56T4b, and 56T5b formed in the dielectric layer 56, respectively.

FIG. 5B shows a patterned surface of the eighth dielectric layer 58. Conductor layers 581, 582, and 583 are formed on the patterned surface of the dielectric layer 58.

Through holes 58T1a, 58T1b, 58T2a, 58T2b, 58T3a, 58T3b, 58T4a, 58T4b, and 58T5b shown in FIG. 5B are connected to the through holes 57T1a, 57T1b, 57T2a, 57T2b, 57T3a, 57T3b, 57T4a, 57T4b, and 57T5b formed in the dielectric layer 57, respectively. Through holes 58T5a, 58T6a, and 58T6b shown in FIG. 5B are connected to the conductor layers 581, 582, and 583, respectively.

FIG. 5C shows a patterned surface of each of the ninth to seventeenth dielectric layers 59 to 67. The dielectric layers 59 to 67 each have through holes 59T1a, 59T1b, 59T2a, 59T2b, 59T3a, 59T3b, 59T4a, 59T4b, 59T5a, 59T5b, 59T6a, and 59T6b. The through holes 59T1a, 59T1b, 59T2a, 59T2b, 59T3a, 59T3b, 59T4a, 59T4b, 59T5a, 59T5b, 59T6a, and 59T6b formed in the dielectric layer 59 are connected to the through holes 58T1a, 58T1b, 58T2a, 58T2b, 58T3a, 58T3b, 58T4a, 58T4b, 58T5a, 58T5b, 58T6a, and 58T6b formed in the dielectric layer 58, respectively. In the dielectric layers 59 to 67, every vertically adjacent through holes denoted by the same reference signs are connected to each other.

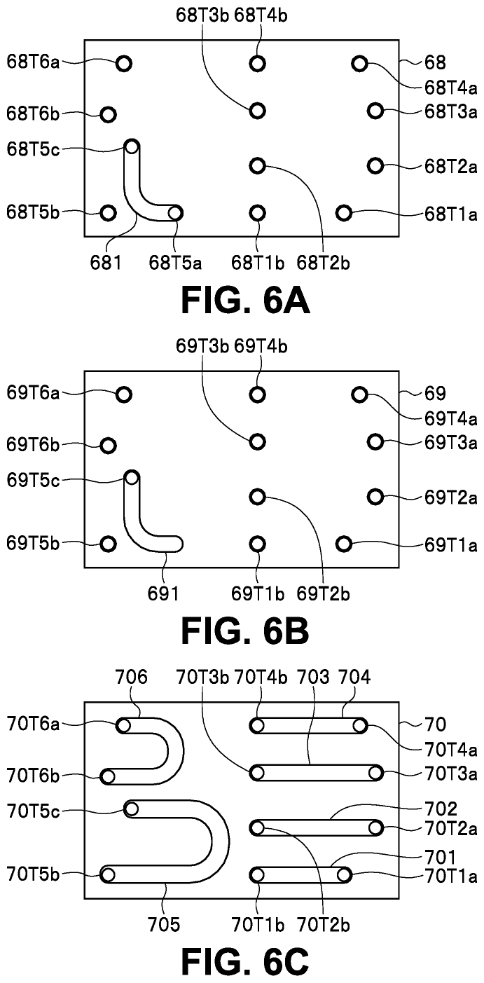

FIG. 6A shows a patterned surface of the eighteenth dielectric layer 68. An inductor conductor layer 681 is formed on the patterned surface of the dielectric layer 68.

Through holes 68T1a, 68T1b, 68T2a, 68T2b, 68T3a, 68T3b, 68T4a, 68T4b, 68T5b, 68T6a, and 68T6b shown in FIG. 6A are connected to the through holes 59T1a, 59T1b, 59T2a, 59T2b, 59T3a, 59T3b, 59T4a, 59T4b, 59T5b, 59T6a, and 59T6b formed in the dielectric layer 67, respectively.

The conductor layer 681 includes a first end and a second end. The through hole 68T5a shown in FIG. 6A and the through hole 59T5a formed in the dielectric layer 67 are connected to a portion of the conductor layer 681 near the first end. The through hole 68T5c shown in FIG. 6A is connected to a portion of the conductor layer 681 near the second end.

FIG. 6B shows a patterned surface of the nineteenth dielectric layer 69. An inductor conductor layer 691 is formed on the patterned surface of the dielectric layer 69.

Through holes 69T1a, 69T1b, 69T2a, 69T2b, 69T3a, 69T3b, 69T4a, 69T4b, 69T5b, 69T6a, and 69T6b shown in FIG. 6B are connected to the through holes 68T1a, 68T1b, 68T2a, 68T2b, 68T3a, 68T3b, 68T4a, 68T4b, 68T5b, 68T6a, and 68T6b formed in the dielectric layer 68, respectively.

The conductor layer 691 includes a first end and a second end. The through hole 68T5a formed in the dielectric layer 68 is connected to a portion of the conductor layer 691 near the first end. The through hole 69T5c shown in FIG. 6B and the through hole 68T5c formed in the dielectric layer 68 are connected to a portion of the conductor layer 681 near the second end.

FIG. 6C shows a patterned surface of the twentieth dielectric layer 70. Resonator conductor layers 701, 702, 703, and 704 and inductor conductor layers 705 and 706 are formed on the patterned surface of the dielectric layer 70. Each of the conductor layers 701 to 706 includes a first end and a second end.

The through hole 70T1a shown in FIG. 6C and the through hole 69T1a formed in the dielectric layer 69 are connected to a portion of the conductor layer 701 near the first end. The through hole 70T1b shown in FIG. 6C and the through hole 69T1b formed in the dielectric layer 69 are connected to a portion of the conductor layer 701 near the second end.

The through hole 70T2a shown in FIG. 6C and the through hole 69T2a formed in the dielectric layer 69 are connected to a portion of the conductor layer 702 near the first end. The through hole 70T2b shown in FIG. 6C and the through hole 69T2b formed in the dielectric layer 69 are connected to a portion of the conductor layer 702 near the second end.

The through hole 70T3a shown in FIG. 6C and the through hole 69T3a formed in the dielectric layer 69 are connected to a portion of the conductor layer 703 near the first end. The through hole 70T3b shown in FIG. 6C and the through hole 69T3b formed in the dielectric layer 69 are connected to a portion of the conductor layer 703 near the second end.

The through hole 70T4a shown in FIG. 6C and the through hole 69T4a formed in the dielectric layer 69 are connected to a portion of the conductor layer 704 near the first end. The through hole 70T4b shown in FIG. 6C and the through hole 69T4b formed in the dielectric layer 69 are connected to a portion of the conductor layer 704 near the second end.

The through hole 70T5b shown in FIG. 6C and the through hole 69T5b formed in the dielectric layer 69 are connected to a portion of the conductor layer 705 near the first end. The through hole 70T5c shown in FIG. 6C and the through hole 69T5c formed in the dielectric layer 69 are connected to a portion of the conductor layer 705 near the second end.

The through hole 70T6a shown in FIG. 6C and the through hole 69T6a formed in the dielectric layer 69 are connected to a portion of the conductor layer 706 near the first end. The through hole 70T6b shown in FIG. 6C and the through hole 69T6b formed in the dielectric layer 69 are connected to a portion of the conductor layer 706 near the second end.

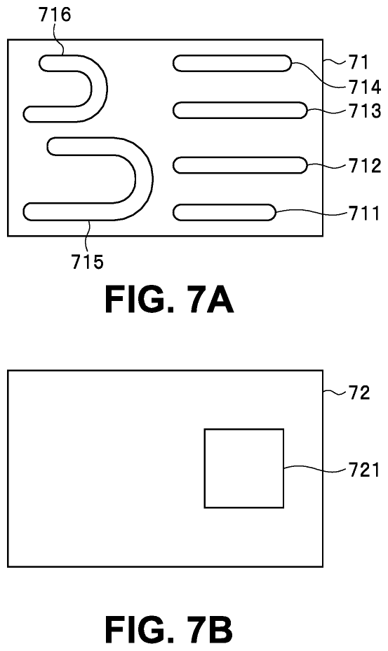

FIG. 7A shows a patterned surface of the twenty-first dielectric layer 71. Resonator conductor layers 711, 712, 713, and 714 and inductor conductor layers 715 and 716 are formed on the patterned surface of the dielectric layer 71. Each of the conductor layers 711 to 716 includes a first end and a second end.

The through hole 70T1a formed in the dielectric layer 70 is connected to a portion of the conductor layer 711 near the first end. The through hole 70T1b formed in the dielectric layer 70 is connected to a portion of the conductor layer 711 near the second end.

The through hole 70T2a formed in the dielectric layer 70 is connected to a portion of the conductor layer 712 near the first end. The through hole 70T2b formed in the dielectric layer 70 is connected to a portion of the conductor layer 712 near the second end.

The through hole 70T3a formed in the dielectric layer 70 is connected to a portion of the conductor layer 713 near the first end. The through hole 70T3b formed in the dielectric layer 70 is connected to a portion of the conductor layer 713 near the second end.

The through hole 70T4a formed in the dielectric layer 70 is connected to a portion of the conductor layer 714 near the first end. The through hole 70T4b formed in the dielectric layer 70 is connected to a portion of the conductor layer 714 near the second end.

The through hole 70T5b formed in the dielectric layer 70 is connected to a portion of the conductor layer 715 near the second end. The through hole 70T5c formed in the dielectric layer 70 is connected to a portion of the conductor layer 715 near the second end.

The through hole 70T6a formed in the dielectric layer 70 is connected to a portion of the conductor layer 716 near the first end. The through hole 70T6b formed in the dielectric layer 70 is connected to a portion of the conductor layer 716 near the second end.

FIG. 7B shows a patterned surface of the twenty-second dielectric layer 72. A mark 721 is formed on the patterned surface of the dielectric layer 72.

The stack 50 shown in FIG. 2 is formed by stacking the first to twenty-second dielectric layers 51 to 72 such that the patterned surface of the first dielectric layer 51 serves as the bottom surface 50A of the stack 50 and the surface of the twenty-second dielectric layer 72 opposite to the patterned surface thereof serves as the top surface 50B of the stack 50.

Each of the plurality of through holes shown in FIG. 3A to FIG. 6C is connected to, when the first to twenty-first dielectric layers 51 to 71 are stacked, a conductor layer overlapping in the stacking direction T or to another through hole overlapping in the stacking direction T. Of the plurality of through holes shown in FIG. 3A to FIG. 6C, the ones located within a terminal or a conductor layer are connected to the terminal or conductor layer.

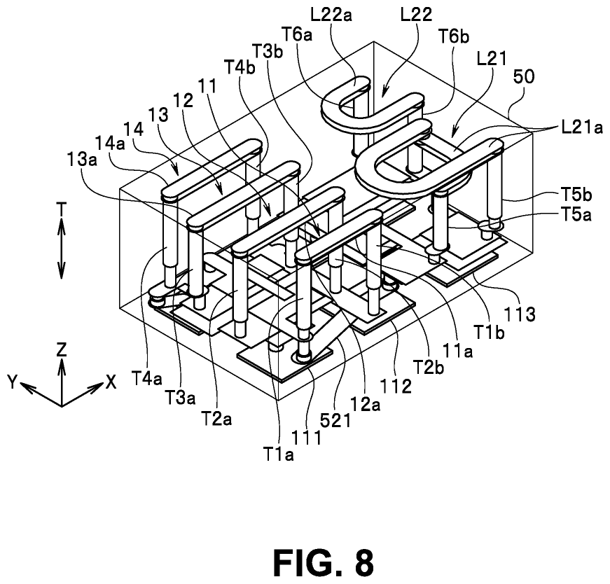

FIG. 8 shows the inside of the stack 50 formed by stacking the first to twenty-second dielectric layers 51 to 72. As shown in FIG. 8, the plurality of conductor layers and the plurality of through holes shown in FIG. 3A to FIG. 7A are stacked together inside the stack 50. Note that FIG. 8 omits the mark 721.

Correspondences between the circuit components of the electronic component 1 shown in FIG. 1 and the internal components of the stack 50 shown in FIG. 3A to FIG. 7B will now be described. Components of the first filter 10 will initially be described. The resonator 11 is composed of the conductor layers 701 and 711, the through holes 56T1a, 57T1a, 58T1a, 59T1a, 68T1a, 69T1a, and 70T1a, and the through holes 53T1b, 54T1b, 55T1b, 56T1b, 57T1b, 58T1b, 59T1b, 68T1b, 69T1b, and 70T1b.

The resonator 12 is composed of the conductor layers 702 and 712, the through holes 55T2a, 56T2a, 57T2a, 58T2a, 59T2a, 68T2a, 69T2a, and 70T2a, and the through holes 53T2b, 54T2b, 55T2b, 56T2b, 57T2b, 58T2b, 59T2b, 68T2b, 69T2b, and 70T2b.

The resonator 13 is composed of the conductor layers 703 and 713, the through holes 55T3a, 56T3a, 57T3a, 58T3a, 59T3a, 68T3a, 69T3a, and 70T3a, and the through holes 53T3b, 54T3b, 55T3b, 56T3b, 57T3b, 58T3b, 59T3b, 68T3b, 69T3b, and 70T3b.

The resonator 14 is composed of the conductor layers 704 and 714, the through holes 54T4a, 55T4a, 56T4a, 57T4a, 58T4a, 59T4a, 68T4a, 69T4a, and 70T4a, and the through holes 53T4b, 54T4b, 55T4b, 56T4b, 57T4b, 58T4b, 59T4b, 68T4b, 69T4b, and 70T4b.

The capacitor C11 is composed of the conductor layers 521 and 531 and the dielectric layer 52 interposed between those conductor layers. The capacitor C12 is composed of the conductor layers 531 and 551 and the dielectric layers 53 and 54 interposed between those conductor layers. The capacitor C13 is composed of the conductor layers 531 and 552 and the dielectric layers 53 and 54 interposed between those conductor layers. The capacitor C14 is composed of the conductor layers 531 and 541 and the dielectric layer 53 interposed between those conductor layers.

The capacitor C15 is composed of the conductor layers 551 and 561 and the dielectric layer 55 interposed between those conductor layers. The capacitor C16 is composed of the conductor layers 552 and 562 and the dielectric layer 55 interposed between those conductor layers. The capacitor C17 is composed of the conductor layers 561 and 571 and the dielectric layer 56 interposed between those conductor layers. The capacitor C18 is composed of the conductor layers 562 and 571 and the dielectric layer 56 interposed between those conductor layers.

Next, components of the high-pass filter circuit 21 of the second filter 20 will be described. The inductor L21 is composed of the conductor layers 681, 691, 705, and 715, the through holes 58T5a, 59T5a, and 68T5a, the through holes 56T5b, 57T5b, 58T5b, 59T5b, 68T5b, 69T5b, and 70T5b, and the through holes 68T5c, 69T5c, and 70T5c.

The inductor L22 is composed of the conductor layers 706 and 716, the through holes 58T6a, 59T6a, 68T6a, 69T6a, and 70T6a, and the through holes 58T6b, 59T6b, 68T6b, 69T6b, and 70T6b.

The capacitor C21 is composed of the conductor layers 553 and 563 and the dielectric layer 55 interposed between those conductor layers. The capacitor C22 is composed of the conductor layers 554 and 564 and the dielectric layer 55 interposed between those conductor layers. The capacitor C23 is composed of the conductor layers 543 and 554 and the dielectric layer 54 interposed between those conductor layers. The capacitor C24 is composed of the conductor layers 532 and 542 and the dielectric layer 53 interposed between those conductor layers. The capacitor C25 is composed of the conductor layers 554 and 565 and the dielectric layer 55 interposed between those conductor layers.

Next, components of the low-pass filter circuit 22 of the second filter 20 will be described. The inductor L23 is composed of the conductor layer 522. The capacitor C26 is composed of the conductor layers 533 and 543 and the dielectric layer 53 interposed between those conductor layers. The capacitor C27 is composed of the conductor layers 534 and 543 and the dielectric layer 53 interposed between those conductor layers.

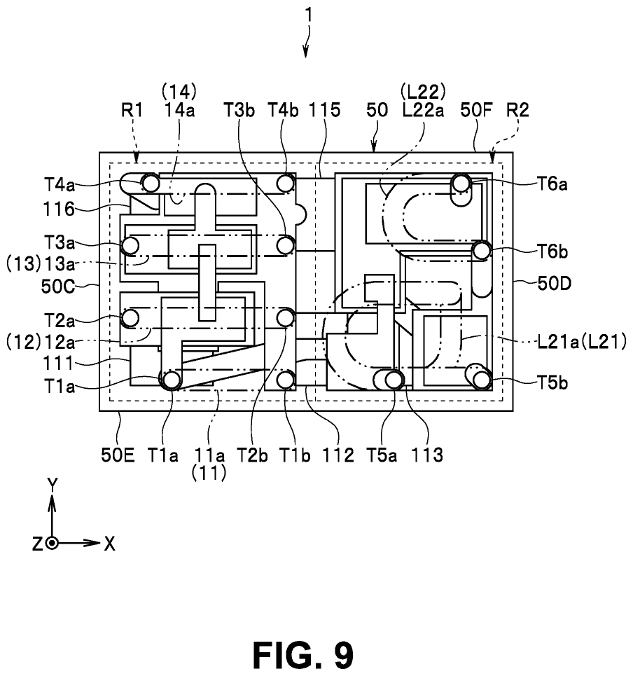

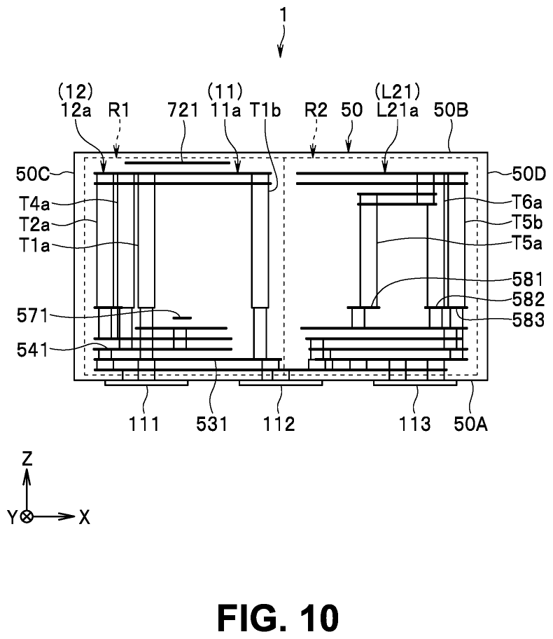

Next, structural features of the electronic component 1 according to the present embodiment will be described with reference to FIG. 1 and FIG. 8 to FIG. 10. FIG. 9 is a plan view showing the inside of the stack 50. FIG. 10 is a side view showing the inside of the stack 50.

The resonator 11 includes two through hole lines T1a and T1b and a conductor layer portion 11a connecting the two through hole lines T1a and T1b. The through hole line T1a is constituted by connecting the through holes 56T1a, 57T1a, 58T1a, 59T1a, 68T1a, and 69T1a in series. The through hole line T1b is constituted by connecting the through holes 53T1b, 54T1b, 55T1b, 56T1b, 57T1b, 58T1b, 59T1b, 68T1b, and 69T1b in series. The conductor layer portion 11a is composed of the two conductor layers 701 and 711 connected to each other via the through holes 70T1a and 70T1b. The two through hole lines T1a and T1b and the conductor layer portion 11a are connected in the order of the through hole line T1a, the conductor layer portion 11a, and the through hole line T1b to circle around an axis parallel to the Y direction.

The resonator 12 includes two through hole lines T2a and T2b and a conductor layer portion 12a connecting the two through hole lines T2a and T2b. The through hole line T2a is constituted by connecting the through holes 55T2a, 56T2a, 57T2a, 58T2a, 59T2a, 68T2a, and 69T2a in series. The through hole line T2b is constituted by connecting the through holes 53T2b, 54T2b, 55T2b, 56T2b, 57T2b, 58T2b, 59T2b, 68T2b, and 69T2b in series. The conductor layer portion 12a is composed of the two conductor layers 702 and 712 connected to each other via the through holes 70T2a and 70T2b. The two through hole lines T2a and T2b and the conductor layer portion 12a are connected in the order of the through hole line T2a, the conductor layer portion 12a, and the through hole line T2b to circle around an axis parallel to the Y direction.

The resonator 13 includes two through hole lines T3a and T3b and a conductor layer portion 13a connecting the two through hole lines T3a and T3b. The through hole line T3a is constituted by connecting the through holes 55T3a, 56T3a, 57T3a, 58T3a, 59T3a, 68T3a, and 69T3a in series. The through hole line T3b is constituted by connecting the through holes 53T3b, 54T3b, 55T3b, 56T3b, 57T3b, 58T3b, 59T3b, 68T3b, and 69T3b in series. The conductor layer portion 13a is composed of the two conductor layers 703 and 713 connected to each other via the through holes 70T3a and 70T3b. The two through hole lines T3a and T3b and the conductor layer portion 13a are connected in the order of the through hole line T3a, the conductor layer portion 13a, and the through hole line T3b to circle around an axis parallel to the Y direction.

The resonator 14 includes two through hole lines T4a and T4b and a conductor layer portion 14a connecting the two through hole lines T4a and T4b. The through hole line T4a is constituted by connecting the through holes 54T4a, 55T4a, 56T4a, 57T4a, 58T4a, 59T4a, 68T4a, and 69T4a in series. The through hole line T4b is constituted by connecting the through holes 53T4b, 54T4b, 55T4b, 56T4b, 57T4b, 58T4b, 59T4b, 68T4b, and 69T4b in series. The conductor layer portion 14a is composed of the conductor layers 704 and 714 connected to each other via the through holes 70T4a and 70T4b. The two through hole lines T4a and T4b and the conductor layer portion 14a are connected in the order of the through hole line T4a, the conductor layer portion 14a, and the through hole line T4b to circle around an axis parallel to the Y direction.

The inductor L21 includes two through hole lines T5a and T5b and a conductor layer portion L21a connecting the two through hole lines T5a and T5b. The through hole line T5a is constituted by connecting the through holes 58T5a and 59T5a in series. The through hole line T5b is constituted by connecting the through holes 56T5b, 57T5b, 58T5b, 59T5b, 68T5b, and 69T5b in series. The conductor layer portion L21a is composed of the four conductor layers 681, 691, 705, and 715 connected to each other via the through holes 68T5a, 68T5c, 69T5c, 70T5b, and 70T5c.

The inductor L22 includes two through hole lines T6a and T6b and a conductor layer portion L22a connecting the two through hole lines T6a and T6b. The through hole line T6a is constituted by connecting the through holes 58T6a, 59T6a, 68T6a, and 69T6a in series. The through hole line T6b is constituted by connecting the through holes 58T6b, 59T6b, 68T6b, and 69T6b in series. The conductor layer portion L22a is composed of the two conductor layers 706 and 716 connected to each other via the through holes 70T6a and 70T6b.

In the circuit configuration, the through hole lines T1b, T2b, T3b, and T4b are provided between the conductor layer portions 11a, 12a, 13a, and 14a and the ground, respectively. The through hole lines T1b, T2b, T3b, and T4b are arranged in a shorter side direction of the planar shape of the stack 50 when seen from the stacking direction T, in other words, the Y direction.

The region inside the stack 50 is divided into a first region R1 and a second region R2 in each of which at least one element is arranged, by the through hole lines T1b, T2b, T3b, and T4b. The first region R1 is a region located on the −X direction side of the through hole lines T1b, T2b, T3b, and T4b. The second region R2 is a region located on the X direction side of the through hole lines T1b, T2b, T3b, and T4b. The first region R1 and the second region R2 may include but need not include the through hole lines T1b, T2b, T3b, and T4b. In the present embodiment, the first region R1 is assumed to include the through hole lines T1b, T2b, T3b, and T4b. The through hole lines T1b, T2b, T3b, and T4b substantially divide a greater part of the first region R1 (main part of the first region R1) and the second region R2. The first region R1 and the second region R2 are arranged in this order in a longitudinal direction of the planar shape of the stack 50 when seen from the stacking direction T, in other words, the X direction.

In the first region R1, at least one first element is arranged. The first filter 10 includes at least one first element. In the present embodiment, in particular, the resonators 11 to 14 and the capacitors C11 to C18 of the first filter 10 are arranged as the at least one first element in the first region R1. More concretely, a plurality of conductor layers and a plurality of through holes for constituting the resonators 11 to 14 and the capacitors C11 to C18 are arranged in the first region R1.

In the second region R2, at least one second element is arranged. The second filter 20 includes at least one second element. In the present embodiment, in particular, the inductors L21 to L23 and the capacitors C21 to C27 of the second filter 20 are arranged as the at least one second element in the second region R2. More concretely, a plurality of conductor layers and a plurality of through holes for constituting the inductors L21 to L23 and the capacitors C21 to C27 are arranged in the second region R2.

Now, the operation and effects of the electronic component 1 according to the present embodiment will be described. In the present embodiment, the stack 50 includes the first region R1 and the second region R2 in each of which at least one element is arranged. The first region R1 and the second region R2 are divided by the through hole lines T1b, T2b, T3b, and T4b. In the circuit configuration, the through hole lines T1b, T2b, T3b, and T4b are provided between the conductor layer portions 11a, 12a, 13a, and 14a and the ground, respectively. In other words, the through hole lines T1b, T2b, T3b, and T4b are components closer to the ground in the resonators 11 to 14. Thus, according to the present embodiment, it is possible to ensure isolation between the first region R1 and the second region R2.

In the present embodiment, a plurality of components of the first filter 10 are arranged in the first region R1, and a plurality of components of the second filter 20 are arranged in the second region R2. According to the present embodiment, it is possible to ensure isolation between the first region R1 and the second region R2 as described above, to thereby be able to ensure isolation between the first filter 10 and the second filter 20.

In the present embodiment, the resonators 11 to 14 are connected in parallel with each other. Thus, according to the present embodiment, the plurality of components closer to the ground can be provided.

The present invention is not limited to the foregoing embodiment, and various modifications may be made thereto. For example, the first filter 10 may include two, three, or four or more resonators each having a similar configuration to that of the resonators 11 to 14, instead of the resonators 11 to 14.

As described above, a multilayer electronic component of the present invention includes: a plurality of resonators; and a stack for integrating the plurality of resonators, the stack including a plurality of dielectric layers stacked together. Each of the plurality of resonators includes a first through hole line, a second through hole line, and a conductor layer portion connecting the first through hole line and the second through hole line. Each of the first through hole line and the second through hole line is constituted by two or more through holes being connected in series. The second through hole line is provided between the conductor layer portion and ground in a circuit configuration. The stack includes a first region and a second region in each of which at least one element is arranged. The first region and the second region are divided by a plurality of second through hole lines.

In the multilayer electronic component of the present invention, the plurality of resonators may be connected in parallel with each other.

The multilayer electronic component of the present invention may further include: a first circuit portion including at least one first element arranged in the first region; and a second circuit portion including at least one second element arranged in the second region. The first circuit portion may further include the plurality of resonators.

In the multilayer electronic component of the present invention, the first region and the second region may be arranged in a longitudinal direction of a planar shape of the stack when seen from a stacking direction of the plurality of dielectric layers. The plurality of second through hole lines may be arranged in a short side direction of the planar shape.

Obviously, many modifications and variations of the present invention are possible in the light of the above teachings. Thus, it is to be understood that, within the scope of the appended claims and equivalents thereof, the present invention may be practiced in other embodiments than the foregoing most preferable embodiment.

What is claimed is:

1. A multilayer electronic component comprising:
a plurality of resonators; and
a stack for integrating the plurality of resonators, the stack including a plurality of dielectric layers stacked together, wherein
each of the plurality of resonators includes a first through hole line, a second through hole line, and a conductor layer portion connecting the first through hole line and the second through hole line,
each of the first through hole line and the second through hole line is constituted by two or more through holes being connected in series,
the second through hole line is provided between the conductor layer portion and ground in a circuit configuration,
the stack includes a first region and a second region in each of which at least one element is arranged, and
the first region and the second region are divided by a plurality of the second through hole lines.

2. The multilayer electronic component according to claim 1, wherein the plurality of resonators are connected in parallel with each other.

3. The multilayer electronic component according to claim 1, further comprising:
a first circuit portion including at least one first element arranged in the first region; and
a second circuit portion including at least one second element arranged in the second region.

4. The multilayer electronic component according to claim 3, wherein the first circuit portion further includes the plurality of resonators.

5. The multilayer electronic component according to claim 1, wherein the first region and the second region are arranged in a longitudinal direction of a planar shape of the stack when seen from a stacking direction of the plurality of dielectric layers.

6. The multilayer electronic component according to claim 5, wherein the plurality of second through hole lines are arranged in a short side direction of the planar shape.
